(19) United States
(12) Patent Application Publication
(10) Pub. No.: US 2008/0286957 A1
(43) Pub. Date: Nov. 20, 2008

(54) METHOD FORMING EPITAXIAL SILICON STRUCTURE

(75) Inventors: Kong-Soo LEE, Gyeonggi-do (KR); Jae-Jong HAN, Seoul (KR); Sang-Jin PARK, Gyeonggi-do (KR); Seok-Jae KIM, Seoul (KR); Yong-Woo HYUNG, Gyeonggi-do (KR); Young-Sub YOU, Gyeonggi-do (KR)

Correspondence Address: VOLENTINE & WHITT PLLC, ONE FREEDOM SQUARE, 11951 FREEDOM DRIVE SUITE 1260, RESTON, VA, 20190, US

(73) Assignee: Samsung Electronics Co., Ltd., Suwon-si (KR)

(21) Appl. No.: 12/122,783

(22) Filed: May 19, 2008

(30) Foreign Application Priority Data
May 18, 2007 (KR) 10-2007-0048394

(51) Int. Cl. H01L 21/3205

(52) U.S. Cl. 438/607; 257/E21.297

(57) ABSTRACT

A method of forming an epitaxial silicon structure is disclosed. The method includes performing a first epitaxial growth process using a first source gas including silicon (Si) and hydrogen chloride (HCl) to form a first epitaxial silicon layer on a substrate, and performing a second epitaxial growth process using a second source gas including silicon (Si) and chlorine (Cl) to form a second epitaxial silicon layer on the first epitaxial silicon layer.

### CROSS-REFERENCE TO RELATED APPLICATION

This application claims priority under 35 U.S.C. §119 to Korean Patent Application No. 10-2007-0048394 filed on May 18, 2007, the subject matter of which is hereby incorporated by reference.

### BACKGROUND OF THE INVENTION

1. Field of the Invention

The present invention relates generally to a method of forming an epitaxial silicon structure and a method of manufacturing a semiconductor device having the same. More particularly, the invention relates to a method of forming an epitaxial silicon structure that effectively fills a contact hole having a relatively great depth.

2. Description of the Related Art

As the integration density of contemporary semiconductor devices is increased, the size of the individual components, such as transistors, is reduced and the separation distance between such components is also reduced. However, as the size of semiconductor components and their corresponding separation distance is reduced within a common plane, the electrical resistance associated with the components may increase, thereby impairing the overall reliability of the semiconductor device.

In an attempt to address this problem, certain semiconductor devices formed from a stacked plurality of semiconductor elements have been developed. In stacked semiconductor devices, substrates containing individual semiconductor components are stacked and electrically connected in a multi-layered structure.

Insulation layers are provided between adjacent substrates, and respective substrates are commonly formed from one or more insulating materials. Electrical connection may typically be provided through a substrate to reach an overlaying substrate. In one approach, selective epitaxial growth is used to form a conductive path through a substrate. For example, one or more insulating layer(s) may be formed on a substrate containing a plurality of semiconductor components (or “elements”) and one or more contact hole(s). A contact hole may be formed in the insulating layer to expose the surface of the substrate. Then, a selective epitaxial growth process is performed in relation to the exposed substrate surface to form an electrical contact filling the contact hole. The material grown using the epitaxial growth process may, as desired, extend over the surface of the insulating layer forming a conductive layer electrically connected to the contact. In certain applications, a substrate may be formed from single crystal silicon. Thus, the contact and the epitaxial silicon layer grown from the substrate material will also have a similar single crystal structure.

As is well understood in the art, contact holes are characterized by greater depth than width. That is, contact holes generally have a high aspect ratio. This particular geometry poses some potential problems to a process designer.

For example, high temperature processes may be performed at a temperature of about 800° C. in order to fill the contact hole with epitaxial silicon. However, in certain circumstances, such processes may exceed the heat budget for the device being manufactured and the quality of the epitaxial silicon filling the contact hole is reduced. Further, the substrate portion exposed through the contact hole may correspond to a source/drain region doped with impurities. Where the source/drain region is a highly doping substrate region, the selective epitaxial growth process may start when a low-density doping region is exposed after silicon of the high-density doping area has been completely removed. For this reason, voids or seams may be formed in the epitaxial silicon filling the contact hole. In particular, such voids or seams may be formed in a portion of the epitaxial silicon adjacent to the source/drain regions of the substrate. When a contact or a plug includes epitaxial silicon having the voids or seams, the electrical characteristics and reliability of the semiconductor device may be impaired.

### SUMMARY OF THE INVENTION

Embodiments of the invention provide a method of forming an epitaxial silicon structure having reduced defects such as voids and/or seams. Embodiments of the invention provide a method of manufacturing a semiconductor device including an improved epitaxial silicon structure.

In one embodiment, the invention provides a method of forming an epitaxial silicon structure, comprising; performing a first epitaxial growth process using a first source gas including silicon (Si) and hydrogen chloride (HCl) to form a first epitaxial silicon layer on a substrate, and performing a second epitaxial growth process using a second source gas including silicon (Si) and chlorine (Cl) to form a second epitaxial silicon layer on the first epitaxial silicon layer.

In another embodiment, the invention provides a method of manufacturing a semiconductor device, comprising; forming an insulation layer on a substrate, forming a contact hole through the insulation layer to expose a portion of the substrate, performing a first selective epitaxial growth process using a first source gas including silicon (Si) and hydrogen chloride (HCl) to form a first epitaxial silicon layer in the contact hole, and performing a second selective epitaxial growth process using a second source gas including silicon (Si) and chlorine (Cl) to form a second epitaxial silicon layer on the first epitaxial silicon layer.

### BRIEF DESCRIPTION OF THE DRAWINGS

FIGS. 1 and 2 are cross-sectional views illustrating a method of forming an epitaxial silicon structure in accordance with embodiments of the invention; and

FIGS. 3 to 6 are cross-sectional views illustrating a method of manufacturing a semiconductor device including an epitaxial silicon structure in accordance with embodiments of the invention.

### DESCRIPTION OF EMBODIMENTS

Several embodiments of the invention will be described with reference to the accompanying drawings. The present invention may, however, be embodied in many different forms and should not be construed as being limited to only the illustrated embodiments. Rather, these example embodiments are provided as teaching examples. In the drawings, the size and/or relative size of various layers and/or regions may be exaggerated for clarity. Throughout the drawings and written description, like reference numerals refer to like or similar elements.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular example embodiments only and is not intended to be limiting of the present invention. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Embodiments of the invention are described herein with reference to cross-sectional illustrations that are schematic illustrations of idealized example embodiments (and intermediate structures) of the present invention. As such, variations from the shapes of the illustrations as a result, for example, of manufacturing techniques and/or tolerances, are to be expected. Thus, example embodiments of the present invention should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the present invention.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

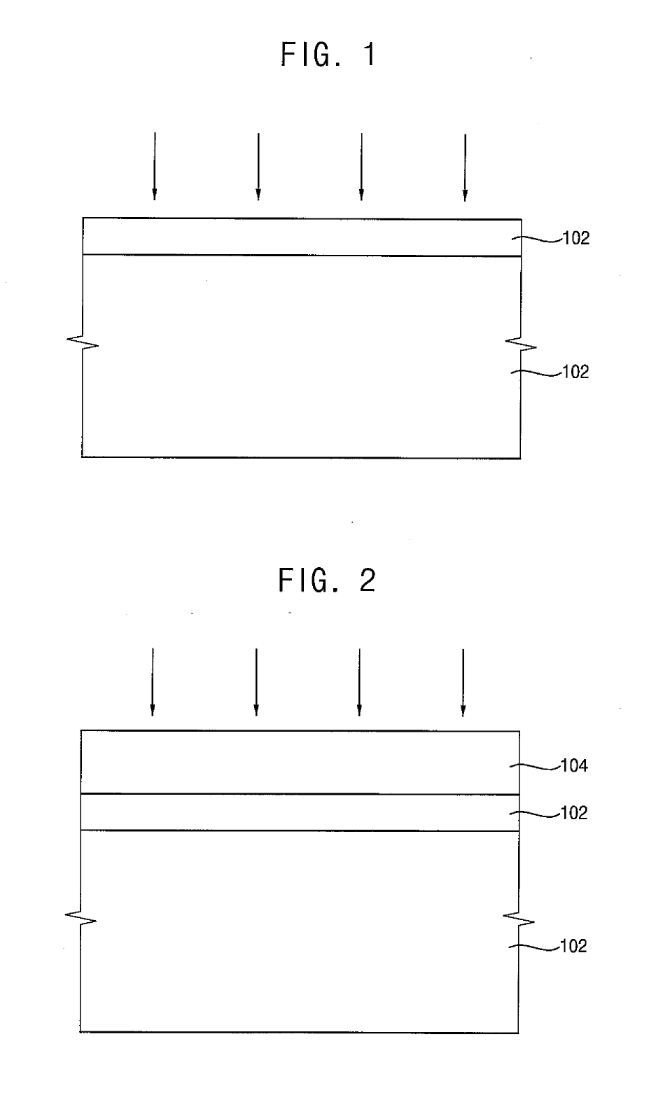

FIGS. 1 and 2 are cross-sectional views illustrating a method of forming an epitaxial silicon structure in accordance with some example embodiments of the present invention.

Referring to FIG. 1, a substrate 100 is loaded into a process chamber. The substrate 100 may include a semiconductor substrate containing silicon (Si) or germanium (Ga), a silicon-on-isolator (SOI) substrate, a germanium-on-insulator (GOI) substrate, etc. In an example embodiment, the substrate 100 may include a semiconductor substrate containing silicon that has a single crystalline structure.

In example embodiments, a plurality of conductive patterns and insulating patterns may be provided on the substrate 100.

A first epitaxial growth process may be performed relative to the substrate 100 loaded into the process chamber, thereby forming a first epitaxial silicon layer 102 on the substrate 100 having a defined conductive/insulating pattern.

In one embodiment of the invention, a first source gas including silicon (Si) and hydrogen chloride (HCl) are provided to the process chamber where the substrate 100 is loaded. The first source gas may additionally include a hydrogen (H₂) gas. The process chamber is heated to a temperature of about 400° C. to about 760° C., and held at a pressure of about 100 Pa to about 1,000 Pa. For example, the first source gas may include dichlorosilane (SiH₂Cl₂ or DCS), silane (SiH₄), hexachlorodisilane (HCD; Si₂H₆), etc.

In the illustrated embodiment, the first epitaxial growth process is performed using the substrate 100 as a seed for the first epitaxial silicon layer 102. Thus, the first epitaxial silicon layer 102 will have a crystalline structure substantially the same as that of the substrate 100. When the first source gas includes silicon, the first epitaxial silicon layer 102 will also include silicon.

In certain embodiments of the invention, chlorine (Cl) contained in hydrogen chloride of the first source gas prevents silicon from adhering to portions of the substrate that do not include silicon. For example, a non-silicon substrate portion may be a conductive pattern region or an insulating pattern region formed on the surface of the substrate 100. Thus, the first epitaxial silicon layer 102 is grown on the substrate 100 using the substrate 100 as the seed material.

Referring to FIG. 2, a second epitaxial silicon layer 104 is formed on the first epitaxial silicon layer 102 using a second epitaxial growth process.

In one embodiment, the first and the second epitaxial growth processes are sequentially performed in-situ. That is, the first and the second epitaxial growth processes may be carried out without a vacuum break in constituent process chambers.

In another embodiment, the first and the second epitaxial growth processes are performed ex-situ. For example, the upper surface of the first epitaxial silicon layer 102 may be cleaned following a formation of first epitaxial silicon layer 102, and then the second epitaxial silicon layer 104 may be formed on the cleaned first epitaxial silicon layer 102. Such a cleaning process may be required to remove a native oxide film from the surface of the first epitaxial silicon layer 102 before performing the second epitaxial growth process. The first epitaxial silicon layer 102 may be cleaned, for example, using a wet cleaning process or a dry cleaning process. In one example, diluted hydrogen fluoride (HF) solution is employed as a cleaning solution in a wet cleaning process associated with first epitaxial silicon layer 102. An ammonia (NH₃) gas or a nitrogen fluoride (NF₄) gas may be used as a cleaning gas in the dry cleaning process. Alternatively, the dry cleaning process may include an in-situ contact cleaning (ICC) process.

In the second epitaxial process, a second source gas including silicon and chlorine (Cl) is introduced to the process chamber holding the substrate 100. The second source gas may further include a hydrogen gas. In one embodiment of the invention, the process chamber is heated to a temperature of about 400° C. to about 700° C., and held at a pressure of about 20 Pa to about 1,000 Pa. The second source gas may include dichlorosilane (DCS), silane, hexachlorodisilane (HCD), etc. In one embodiment of the invention, the second source gas includes silane.

As described above, the second epitaxial growth process is carried out using the first epitaxial silicon layer 102 as a seed material. Hence, the second epitaxial silicon layer 104 will have a crystalline structure substantially the same as that of the first epitaxial silicon layer 102. When the second source gas includes silicon, the second epitaxial silicon layer 102 will also include silicon. Therefore, an epitaxial silicon structure having the first and the second epitaxial silicon layers 102 and 104 may be formed on the substrate 100.

Here again, in certain embodiments, chlorine contained in hydrogen chloride of the second source gas will prevent silicon from adhering to the non-silicon portions of the substrate.

In view of the above first and second epitaxial growth processes, the generation of voids or seams in the epitaxial silicon structure may be effectively prevented. Further, the epitaxial silicon structure may be provided on the substrate 100 with a reduced overall heat budget for the resulting epitaxial silicon structure.

Hereinafter, a method of manufacturing a semiconductor device using processes for forming the epitaxial silicon structure will be described with reference to the accompanying drawings.

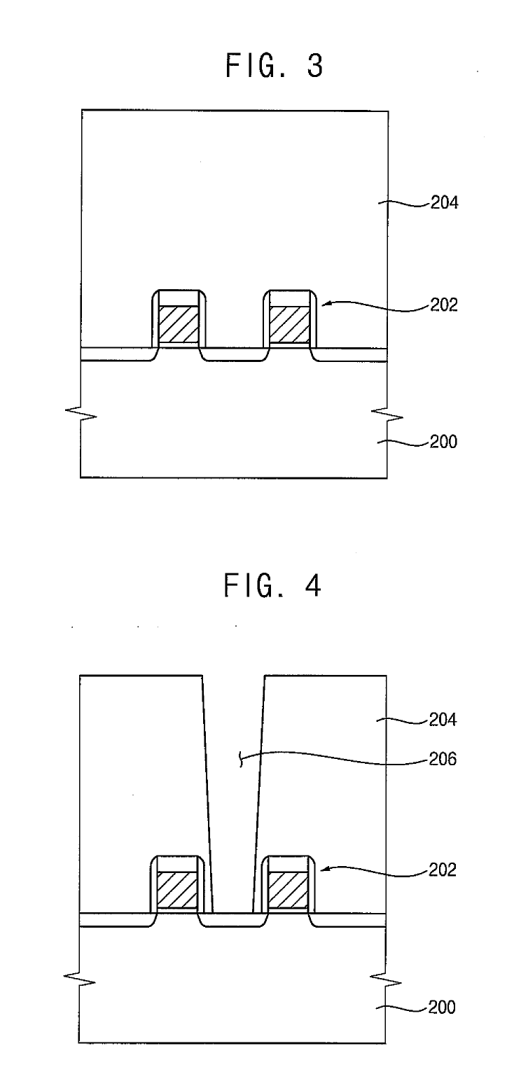

FIGS. 3 to 6 are cross-sectional views illustrating a method of manufacturing the semiconductor device in accordance with embodiments of the invention.

Referring to FIG. 3, an insulation layer 204 is formed on a first substrate 200. The first substrate 200 may include a semiconductor substrate containing silicon or germanium, an SOI substrate, a GOI substrate, etc. Additionally, some structures (i.e., elements or material layer regions) may be provided on the first substrate 200. These structures may include, as a convenient example, transistors 202, conductive pattern regions and/or insulating pattern regions. In illustrated embodiment, the first substrate 200 is assumed to be formed from a single crystal, silicon material.

The insulation layer 204 formed on the first substrate 200 may include an oxide. Examples of oxides in the insulation layer 204 include undoped silicate glass (USG), boro-phosphor silicate glass (BPSG), phosphor silicate glass (PSG), flowable oxide (FOX), plasma enhanced-tetraethylorthosilicate (PE-TEOS), tonensilazene (TOSZ), fluoride silicate glass (FSG), etc.

Referring to FIG. 4, the insulation layer 204 is selectively etched to form a contact hole 206 exposing a portion of the first substrate 200.

In one embodiment of the invention, a mask layer may be formed on the insulation layer 204 and a photoresist pattern may be formed on the mask layer. The mask layer may be partially etched using the photoresist pattern as an etching mask, thereby forming a mask on the insulation layer 204. After forming the mask, the photoresist pattern may be removed by an ashing process and/or a strip process. Alternatively, the photoresist pattern may be consumed in an etching process for forming the contact hole 206. The insulation layer 204 may be partially etched using the mask as an etching mask so that the contact hole 206 exposing a portion of the first substrate 200 is provided through the insulation layer 204. After forming the contact hole 206, the mask may be removed from insulation layer 204 using a wet etching process or a dry etching process.

In certain embodiments of the invention, the contact hole will have a depth of about 1,000 Å to about 3,000 Å, as measured from the upper surface of insulation layer 204. An exposed portion of the first substrate 200 through the contact hole 206 may correspond to a source/drain region of the transistor 202 doped with impurities.

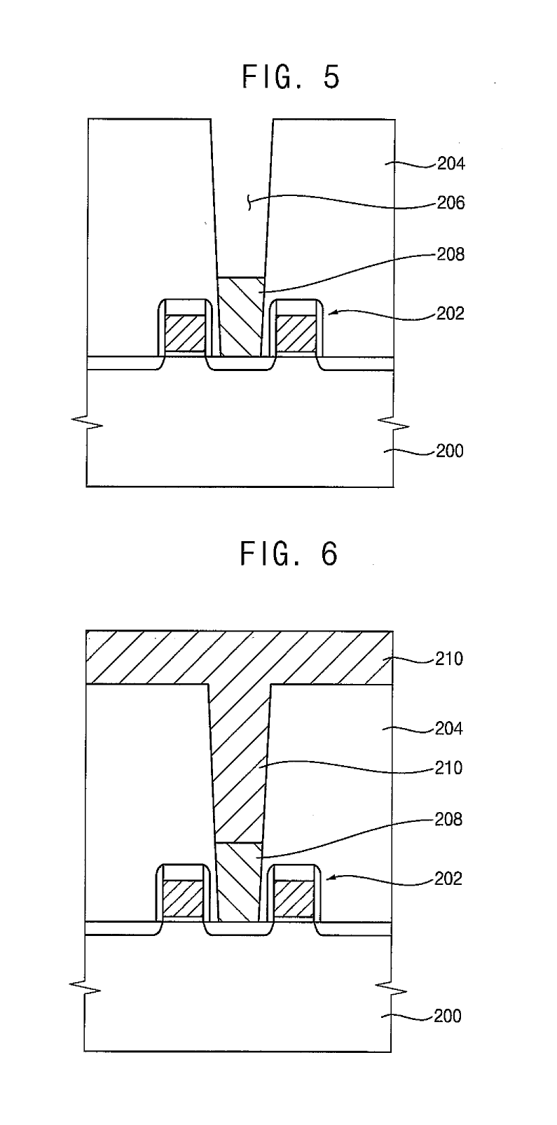

Referring to FIG. 5, the first substrate 200 including the insulation layer 204 is loaded into a process chamber. A first selective epitaxial growth process is performed on the first substrate 200 to form a first epitaxial silicon layer 208. In certain embodiments of the invention, a first source gas including silicon and hydrogen chloride is introduced into the process chamber. The first source gas may additionally include a hydrogen gas. The process chamber is heated to a temperature of about 400° C. to about 760° C. and held at a pressure of about 100 Pa to about 1,000 Pa. The first source gas may include dichlorosilane (DCS), silane, hexachlorodisilane (HCD), etc.

In the illustrated embodiment, the first selective epitaxial growth process is carried out in relation to a portion of first substrate 100 exposed through the contact hole 206. This exposed substrate portion serves as a seed material for the first selective epitaxial growth process. Thus, the first epitaxial silicon layer 208 provided on the exposed portion of the first substrate 200 will have a crystalline structure substantially the same as the crystalline structure of the first substrate 200. The first epitaxial silicon layer 208 is formed to partially fill the contact hole 206. Thus, where the first substrate 200 has a single crystal structure, the first epitaxial silicon layer 208 will also have a single crystal structure. Since the first source gas including silicon is provided during the first selective epitaxial growth process, first epitaxial silicon layer 208 will include silicon.

During the first selective epitaxial growth process, the first epitaxial silicon layer 208 is selectively formed on only the exposed portion of first substrate 200 because of the chlorine within the hydrogen chloride of the first source gas as described above. When the insulation layer 204 is silicon oxide, for example, a polysilicon layer may be formed on the insulation layer 204 due to silicon contained in the first source gas. However, the chlorine contained in hydrogen chloride of the first source gas restricts formation of the polysilicon layer on the insulation layer 204. That is, chlorine in hydrogen chloride prevents silicon in the insulation layer 204 from adhering to silicon included in the first source gas, thereby preventing the polysilicon layer from growing on the surface of the insulation layer 204.

In the illustrated embodiment, the portion of the first substrate 200 exposed through the contact hole 206 corresponds to a source/drain region doped with impurities. When the source/drain region includes a high impurity concentration and the first source gas includes chlorine, the source/drain region may be partially etched by chlorine, thereby deteriorating the impurity concentration of the source/drain region. To prevent this outcome, hydrogen chloride may be added to the first source gas to ensure maintenance of a proper impurity concentration and the desired area of the source/drain region.

When the first source gas including hydrogen chloride is employed to form the first epitaxial silicon layer 208, the first selective epitaxial growth process may be performed at a temperature of about 800° C. However, when the first selective epitaxial growth process is performed at a high temperature, an excessive heat budget may be caused in the first epitaxial silicon layer 208. To effectively reduce the excessive heat budget of the first epitaxial silicon layer 208, the first selective epitaxial growth process may be performed at a temperature of about 400° C. to about 760° C.

When the first source gas including hydrogen chloride is used to form the first epitaxial silicon layer 208, the first epitaxial silicon layer 208 will be grown at a relatively low speed, so that the fabrication yield of the semiconductor device is relatively low. Therefore, the thickness of the first epitaxial silicon layer 208 may be adjusted considering overall productivity requirements for the manufacture of the semiconductor device. In certain embodiments of the invention, first epitaxial silicon layer 208 will be formed with a thickness of about 300 Å to about 1,000 Å where contact hole 206 has an assumed depth of about 3,000 Å.

Referring to FIG. 6, a second selective epitaxial growth process is performed on first substrate 200 including the first epitaxial silicon layer 208 to form a second epitaxial silicon layer 210 on first epitaxial silicon layer 208. The second epitaxial silicon layer 210 may be formed to completely fill contact hole 206.

In one embodiment, the first and the second epitaxial silicon layers 208 and 210 are formed in-situ. Alternatively, the first and the second epitaxial silicon layers 208 and 210 may be formed ex-situ. When the first and the second epitaxial silicon layers 208 and 210 are formed ex-situ, a cleaning process directed to the surface of the first epitaxial silicon layer 208 may be performed before the second epitaxial silicon layer 210 is formed. With such a cleaning process, a native oxide film may be removed from the surface of the first epitaxial silicon layer 208 before the second selective epitaxial growth process is performed. The surface of the epitaxial silicon layer 210 may be cleaned using a wet cleaning process or a dry cleaning process. In the wet cleaning process, a diluted hydrogen fluoride (HF) solution may be employed as a cleaning solution. Alternatively, an ammonia (NH₃) gas or a nitrogen fluoride (NF₄) gas may be used as a cleaning gas in the dry cleaning process for cleaning the first epitaxial silicon layer 208. Further, the dry cleaning may include an ICC process for effectively cleaning the surface of first epitaxial silicon layer 208.

In example embodiments, the second selective epitaxial growth process may be performed on the first epitaxial silicon layer 208, such that an epitaxial silicon structure formed from the first and the second epitaxial silicon layers 208 and 210 is provided on the first substrate 200 exposed through the 306.

In example embodiments, a second source gas including silicon and chlorine may be provided into the process chamber. The second source gas may additionally include a hydrogen gas. Here, the temperature of the process chamber may range from between about 400° C. to about 700° C., and the pressure thereof from about 20 Pa to about 1,000 Pa. For example, the second source gas includes dichlorosilane (DCS), silane (SiH₄), hexachlorodisilane (HCD), etc.

In the foregoing embodiments, the second selective epitaxial growth process is performed using the first epitaxial silicon layer 208 as a seed. Hence, the second epitaxial silicon layer 210 will have a crystalline structure substantially the same as that of the first epitaxial silicon layer 208. That is, when the first epitaxial silicon layer 208 has a single crystal structure, the second epitaxial layer 210 will also have a single crystal structure. Additionally, when the second source gas including silicon is provided during the second selective epitaxial growth process, the second epitaxial silicon layer 210 will include silicon.

During the second selective epitaxial growth process, the second epitaxial silicon layer 210 is formed on the first epitaxial silicon layer 208, but not the insulation layer 204 because of the chlorine included in the second source gas. That is, chlorine atoms in the second source gas prevent silicon in the insulation layer 204 from adhering to the silicon in the second source gas, such that the second epitaxial silicon layer 210 is formed on the first epitaxial silicon layer 208 and the insulation layer 204 as described above with reference to FIG. 5.

Since the second selective epitaxial growth process is performed using a second source gas including chlorine, the second epitaxial silicon layer 210 may be formed at higher speed as compared with that of the first epitaxial silicon layer 208 formed by the first selective epitaxial growth process. Thus, overall product yield for the semiconductor device may be improved.

In example embodiments, the second epitaxial silicon layer 210 is continuously grown on the insulation layer 204 after the contact hole 206 is filled with the second epitaxial silicon layer 210. Thus, a contact or a plug including the first and the second epitaxial silicon layers 208 and 210 is formed in the contact hole 206. Thus, a second substrate including the second epitaxial silicon layer 210 may be provided on the plug and on the upper surface of the insulation layer 204. In this manner, a second substrate may be formed on the first substrate 200 to provide a stacked semiconductor device.

As described above, the contact or the plug connecting the first substrate 200 to an overlying (i.e.,) second substrate may be formed through the first and the second selective epitaxial growth processes. Thus, a heat budget of the plug may be considerably reduced, and generations of voids and/or seams in the plug may be effectively prevented from the contact or the plug. Further, the yield of the semiconductor device may be improved because the second epitaxial silicon layer may be grown at the high speed.

In example embodiments, the first and the second epitaxial silicon layers 208 and 210 formed through the first and the second selective epitaxial growth processes may be advantageously employed in manufacturing other semiconductor devices such as a phase change random access memory (PRAM) device.

According to example embodiments of the present invention, a first epitaxial silicon layer and a second epitaxial silicon layer may be sequentially formed on a substrate using a first source gas including hydrogen chloride and a second source gas including chlorine, respectively. Hence, generations of voids and/or seams caused by chlorine may be effectively prevented in an epitaxial silicon structure including the first and the second epitaxial silicon layers. Further, a decrease of a yield of a semiconductor device and an excessive heat budget of the epitaxial silicon structure caused by hydrogen chloride may be efficiently prevented. Therefore, a semiconductor device including the epitaxial silicon structure may have an improved reliability and electrical characteristics.

The foregoing is illustrative of the present invention and is not to be construed as limiting thereof. Although a few example embodiments of the present invention have been described, those skilled in the art will readily appreciate that many modifications are possible in the example embodiments without materially departing from the novel teachings and advantages of the present invention. Accordingly, all such modifications are intended to be included within the scope of the present invention as defined in the claims. Therefore, it is to be understood that the foregoing is illustrative of the present invention and is not to be construed as limited to the specific example embodiments disclosed, and that modifications to the disclosed example embodiments, as well as other example embodiments, are intended to be included within the scope of the appended claims. The present invention is defined by the following claims, with equivalents of the claims to be included therein.

What is claimed is:

1. A method of forming an epitaxial silicon structure, comprising:
performing a first epitaxial growth process using a first source gas including silicon (Si) and hydrogen chloride (HCl) to form a first epitaxial silicon layer on a substrate; and
performing a second epitaxial growth process using a second source gas including silicon (Si) and chlorine (Cl) to form a second epitaxial silicon layer on the first epitaxial silicon layer.

2. The method of claim 1, wherein the first source gas comprises dichlorosilane (DSC; SiH₂Cl₂) and the second source gas comprises silane (SiH₄).

3. The method of claim 2, wherein the first source gas further comprises a hydrogen (H₂) gas.

4. The method of claim 2, wherein the second source gas further comprises a hydrogen gas.

5. The method of claim 1, wherein the first epitaxial growth process is performed at a temperature ranging between about 400° C. to about 760° C.

6. The method of claim 1, wherein the second epitaxial growth process is performed at a temperature ranging between about 400° C. to about 700° C.

7. The method of claim 1, wherein the first and the second epitaxial growth processes are performed in-situ.

8. The method of claim 1, further comprising:
cleaning a surface of the first epitaxial silicon layer before performing the second epitaxial growth process.

9. The method of claim 8, wherein cleaning the surface of the first epitaxial silicon layer comprises performing a wet cleaning process using a cleaning solution including hydrogen fluoride (HF).

10. The method of claim 8, wherein cleaning the surface of the first epitaxial silicon layer comprises performing a dry cleaning process using a cleaning gas including ammonium (NH₃) or nitrogen fluoride (NF₄).

11. The method of claim 1, wherein the first epitaxial silicon layer has a crystal structure substantially the same as a crystal structure of the substrate.

12. The method of claim 11, wherein the second epitaxial silicon layer has a crystal structure substantially the same as the crystal structure of the first epitaxial silicon layer.

13. A method of manufacturing a semiconductor device, comprising:
forming an insulation layer on a substrate;
forming a contact hole through the insulation layer to expose a portion of the substrate;
performing a first selective epitaxial growth process using a first source gas including silicon (Si) and hydrogen chloride (HCl) to form a first epitaxial silicon layer in the contact hole; and
performing a second selective epitaxial growth process using a second source gas including silicon (Si) and chlorine (Cl) to form a second epitaxial silicon layer on the first epitaxial silicon layer.

14. The method of claim 13, wherein the insulation layer comprises oxide.

15. The method of claim 13, wherein the portion of the substrate exposed through the contact hole is a source/drain region of the substrate doped with impurities.

16. The method of claim 13, wherein the first selective epitaxial growth process is performed at a temperature ranging from between about 400° C. to about 760° C. and the second selective epitaxial growth process is performed at a temperature ranging between about 400° C. to about 700° C.

17. The method of claim 13, wherein the first epitaxial silicon layer partially fills up the contact hole, and the second epitaxial silicon layer is formed after the first epitaxial silicon layer to completely fill the contact hole.

18. The method of claim 13, wherein the first epitaxial silicon layer has a crystal structure substantially the same as a crystal structure of the substrate and the second epitaxial silicon layer has a crystal structure substantially the same as the crystal structure of the first epitaxial silicon layer.

19. The method of claim 13, further comprising:
forming an additional substrate on the substrate to obtain a stacked semiconductor device.

20. The method of claim 19, wherein the additional substrate comprises the second epitaxial silicon layer.
